(19) United States
(12) Patent Application Publication
(10) Pub. No.: US 2007/0210352 A1
(43) Pub. Date: Sep. 13, 2007

(54) Semiconductor Device And Method Of Manufacturing The Same

(76) Inventors: Yasuhiko Akamatsu, Tokyo (JP); Saifon Son, Tokyo (JP); Shinpei Tsujikawa, Tokyo (JP)

Correspondence Address: MCDERMOTT WILL & EMERY LLP, 600 13TH STREET, N.W., WASHINGTON, DC, 20005-3096, US

(21) Appl. No.: 11/578,332

(22) PCT Filed: Apr. 6, 2005
(86) PCT No.: PCT/JP05/06761

§ 371 Date: Oct. 13, 2006

(30) Foreign Application Priority Data
Apr. 14, 2004 (JP) 2004-118543

(51) Int. Cl. H01L 29/78; H01L 21/336

(52) U.S. Cl. 257/288; 438/197; 257/E29.255; 257/E21.409

(57) ABSTRACT

The present invention relates to a semiconductor device and a method of manufacturing the same, and is intended to keep the electrical resistance of source/drain regions at a low level while preventing diffusion of impurities from a semiconductor film and a sidewall. In order to achieve these objects, the semiconductor device of the present invention is configured as follows. That is, the semiconductor device includes a semiconductor substrate, a gate structure, source/drain regions, a first diffusion preventive film and a sidewall. An insulation film, a second diffusion preventive film and a semiconductor film are stacked from to top in this order to form the gate structure. The semiconductor film contains impurities. The first diffusion preventive film covers a side surface of the gate structure, and also covers the semiconductor substrate while exposing at least a part of the source/drain regions. The sidewall is in contact with the source/drain regions while covering the first diffusion preventive film.

### RELATED APPLICATIONS

This application is the U.S. National Phase under 35 U.S.C. §371 of International Application No. PCT/JP2005/006761, filed on Apr. 6, 2005, which in turn claims the benefit of Japanese Application No. 2004-118543, filed on Apr. 14, 2004, the disclosures of which Applications are incorporated by reference herein.

### TECHNICAL FIELD

The present invention relates to a semiconductor device and a method of manufacturing the same, and is applicable for example to a CMOS (complementary metal oxide semiconductor) transistor.

### BACKGROUND ART

A semiconductor device, such as for example a CMOS transistor, includes a semiconductor substrate, a gate insulation film, a gate electrode, a sidewall and source/drain regions. The gate electrode is provided on the semiconductor substrate with the gate insulation film held therebetween. The gate electrode is formed by a semiconductor material such as polysilicon. The sidewall covers side surfaces of the gate electrode and the gate insulation film. The source/drain regions are formed by implanting impurities such as boron into the semiconductor substrate using for example the sidewall and the gate electrode as a mask.

Techniques relevant to the present invention are introduced in the following publications:

Patent Publication 1: Japanese Patent Application Laid-Open No. 10-173171

Patent Publication 2: Japanese Patent Application Laid-Open No. 2003-318176

Patent Publication 3: Japanese Patent Application Laid-Open No. 11-67760

Patent Publication 4: Japanese Patent Application Laid-Open No. 2000-269490

Patent Publication 5: Japanese Patent Application Laid-Open No. 8-316466

### DISCLOSURE OF INVENTION

Impurities such as for example boron are implanted into the gate electrode. When impurities such as for example boron are implanted to form the source/drain regions, these impurities are likely to be mixed into the sidewall. The impurities introduced in the gate electrode and the sidewall are likely to diffuse into the gate insulation film and further into the semiconductor substrate, especially in a thermal process. This causes deterioration of the semiconductor device such as increase in leakage current, fluctuations in threshold voltage or the like.

Impurity diffusion includes: 1) diffusion directly from the gate electrode into the gate insulation film; 2) diffusion from the gate electrode into the gate insulation film and the semiconductor substrate via the sidewall; and 3) diffusion directly from the sidewall into the gate insulation film and the semiconductor substrate.

The recent development of thinning technique involves thickness reduction of the gate electrode and the like. Thus the impurities implanted into the gate electrode penetrate the gate electrode to reach the gate insulation film, causing a problem also occurring in the case of impurity diffusion.

In response to the above-discussed diffusion 1) and penetration of impurities, a nitride film or an oxy-nitride film may be formed at an interface between the gate electrode and the gate insulation film. Alternatively, the gate insulation film may be formed by a material having a high dielectric constant. These techniques are introduced for example in the above-mentioned patent publications 1, 2 and 3. In response to the above-discussed diffusions 2) and 3), a nitride film or an oxy-nitride film may be formed on side surfaces of the gate electrode and the gate insulation film and on an exposed surface of the semiconductor substrate. This technique is introduced for example in the above-mentioned patent publications 4 and 5. Impurities which are especially boron are thereby prevented from diffusing from the gate electrode and the sidewall into the gate insulation film and the semiconductor substrate.

However, a nitride film or the like formed on an exposed surface of the semiconductor substrate entirely covers the source/drain regions. The nitride film or the like is an insulation layer and has a high electrical resistance accordingly, thereby increasing the electrical resistance of the source/drain regions. As a result, the semiconductor device may suffer from characteristic deterioration such as difficulty in the flow of a drive current of the semiconductor device.

The present invention has been made taking the above-discussed circumstances into consideration. It is an object of the present invention to prevent increase in electrical resistance of the source/drain regions, while preventing impurities from diffusing from the gate electrode and the sidewall into the gate insulation film, and further into the semiconductor substrate defined under the gate insulation film.

A semiconductor device according to the present invention includes: a semiconductor substrate; a gate structure; source/drain regions; a first diffusion preventive film; and a sidewall. The gate structure includes: an insulation film; a semiconductor film; and a second diffusion preventive film. The insulation film is provided on the semiconductor substrate. The semiconductor film is provided on the insulation film and contains impurities. The second diffusion preventive film is provided at an interface between the insulation film and the semiconductor film. The source/drain regions are provided in the semiconductor substrate while being exposed from a surface of the semiconductor substrate. The first diffusion preventive film includes: a first portion covering a side surface of the gate structure; and a second portion extending from the first portion. The second portion covers an exposed surface of the semiconductor substrate while exposing at least a part of the source/drain regions. The sidewall is in contact with the source/drain regions while covering a surface of the first diffusion preventive film opposite to a surface facing the gate structure.

A method of manufacturing a semiconductor device according to the present invention includes steps (a) through (f). In the step (a), a gate structure is provided on a semiconductor substrate. In the step (b), a first diffusion preventive film is provided that includes at least a first portion covering a side surface of the gate structure, and a second portion extending from the first portion while covering a part of an exposed surface of the semiconductor substrate. In the step (c), an offset spacer is provided on the second portion to cover the side surface of the gate structure with the first diffusion preventive film held therebetween. In the step (d), the first diffusion preventive film is removed while leaving the first portion and the second portion unremoved. In the step (e), impurities are implanted into a surface of the semiconductor substrate using the offset spacer as a mask to form source/drain regions to be exposed from the surface of the semiconductor substrate. In the step (f), a sidewall is provided to be in contact with the source/drain regions while covering an exposed side surface of the offset spacer. The step (a) includes steps (a-1) and (a-2). In the step (a-1), an insulation film, a second diffusion preventive film and a semiconductor film are provided from bottom to top in this order in a stacked structure on the semiconductor substrate. In the step (a-2), the insulation film, the second diffusion preventive film and the semiconductor film are removed while leaving a predetermined region unremoved.

According to a semiconductor device and a method of manufacturing the same of the present invention, the source/drain regions are covered only partially by the second portion of the first diffusion preventive film at the surface of the semiconductor substrate. This reduces the electrical resistance of the source/drain regions, thereby allowing a drive current to easily flow in the semiconductor device. Further, impurities are prevented from diffusing from the semiconductor film and a portion of the sidewall arranged on the second portion of the first diffusion preventive film into the insulation film, and further into the semiconductor substrate defined under the insulation film. Thus characteristic deterioration of the semiconductor device is avoided.

Objects, features, aspects and advantages of the present invention will become more apparent from the following detailed description of the present invention when taken in conjunction with the accompanying drawings.

### BRIEF DESCRIPTION OF DRAWINGS

FIG. 1 is a sectional view conceptually showing a process of manufacturing a semiconductor device;

FIG. 2 is a sectional view conceptually showing a process of manufacturing the semiconductor device;

FIG. 3 is a sectional view conceptually showing a process of manufacturing the semiconductor device;

FIG. 4 is a sectional view conceptually showing a process of manufacturing the semiconductor device;

FIG. 5 is a sectional view conceptually showing a process of manufacturing the semiconductor device;

FIG. 6 is a sectional view conceptually showing a process of manufacturing the semiconductor device;

FIG. 7 is a sectional view conceptually showing a process of manufacturing the semiconductor device;

FIG. 8 is a sectional view conceptually showing a process of manufacturing the semiconductor device;

FIG. 9 is a sectional view conceptually showing a process of manufacturing the semiconductor device;

FIG. 10 is a sectional view conceptually showing a semiconductor device of the present invention; and

FIG. 11 is a view conceptually showing the relationship between points and nitrogen concentrations in a nitride film.

### BEST MODE FOR CARRYING OUT THE INVENTION

FIG. 10 is a sectional view conceptually showing a semiconductor device of the present invention. FIGS. 1 through 9 sequentially show processes of manufacturing the semiconductor device shown in FIG. 10. Nitride layers 8, 22 and an insulation film 21 shown in each figure are considerably smaller in thickness than a semiconductor film 23. However, the nitride layers 8, 22 and the insulation film 21 are shown to be thick in each figure to clearly indicate their existence.

In a first step, the insulation film 21 is provided on a semiconductor substrate 1 (FIG. 1). As an example, the semiconductor substrate 1 is an n-type silicon substrate and the insulation film 21 is a silicon oxide film. The insulation film 21 is formed for example by thermal oxidation or radical oxidation of a surface of the semiconductor substrate 1. For the thermal oxidation, H₂O gas, O₂ gas, NO gas, N₂O gas or the like may be used singly or in combination. For the radical oxidation, O₂ radicals are used, for example.

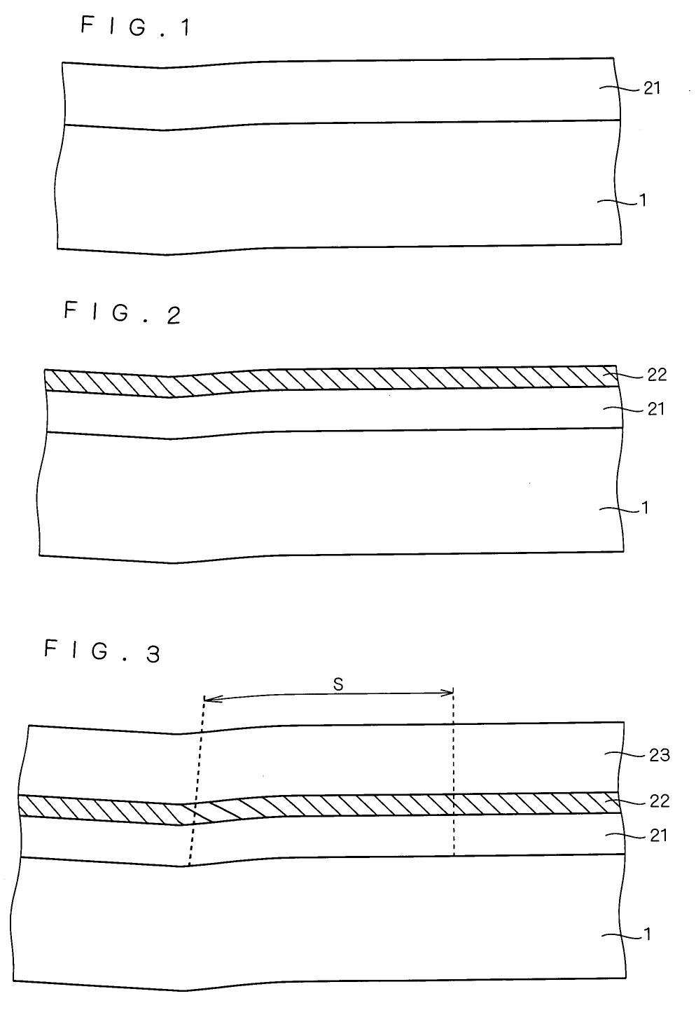

The nitride layer 22 is provided on the insulation film 21 (FIG. 2). The nitride layer 22 is formed for example by a plasma nitriding process on a surface of the insulation film 21 opposite to that facing the semiconductor substrate 1. When the insulation film 21 is a silicon oxide film, for example, the nitride layer 22 is formed into a silicon oxy-nitride film. In a nitride layer formed by a plasma nitriding process, a nitrogen concentration is generally highest in the vicinity of an exposed surface of the nitride layer, and generally becomes lower with a greater depth from the exposed surface. The interface between the insulation film 21 and the nitride layer 22 is clearly shown in FIG. 2, whereas actually, such nitrogen distribution as discussed is formed. This also applies to nitride layers 81, 82, 83 and 84 discussed later.

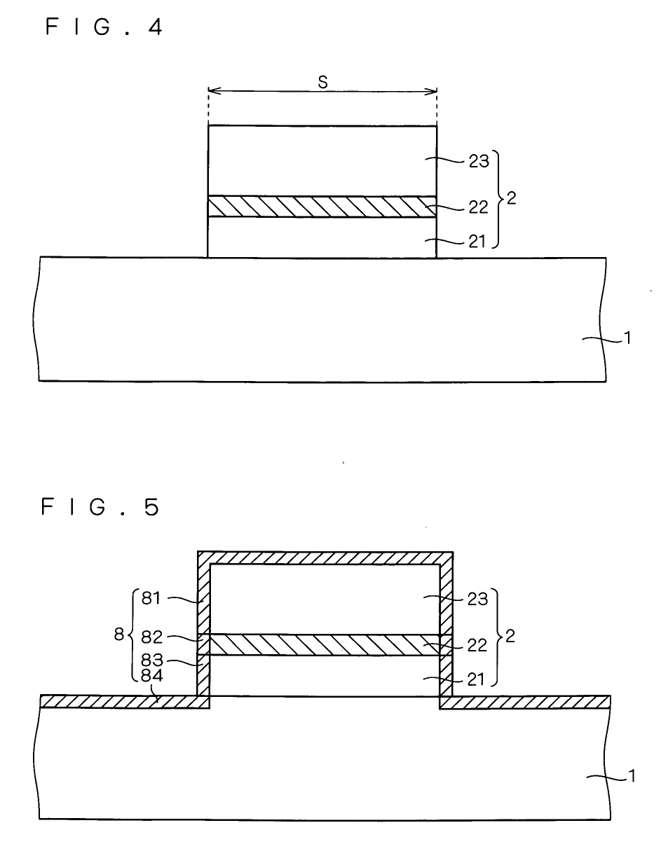

The semiconductor film 23 is provided on the nitride layer 22 (FIG. 3). The semiconductor film 23 may contain polysilicon, amorphous silicon or silicon germanium, for example. The semiconductor film 23 may contain impurities such as boron.

The semiconductor film 23, the nitride layer 22 and the insulation film 21 are removed in this order while leaving a predetermined region S on the semiconductor substrate 1 unremoved. Then a gate structure 2 is defined by the remaining semiconductor film 23, the nitride layer 22 and the insulation film 21 (FIG. 4). As an example, pattern etching using a photoresist may be applied for removing the semiconductor film 23, the nitride layer 22 and the insulation film 21. The insulation film 21 and the semiconductor film 23 forming the gate structure 2 are operative to function as a gate insulation film and a gate electrode.

In a second step, exposed surfaces of the gate structure 2 and the semiconductor substrate 1 are nitrided to form the nitride layers 81, 82, 83 and 84 on exposed surfaces of the semiconductor film 23, the nitride layer 22, the insulation film 21 and the semiconductor substrate 1, respectively (FIG. 5). A plasma nitriding process is employed, for example, for nitriding the exposed surfaces of the gate electrode 2 and the semiconductor substrate 1. As an example, when the semiconductor substrate 1, the insulation film 21 and the semiconductor film 23 are a silicon substrate, a silicon oxide film and a polysilicon film, respectively, the nitride layer 81 is formed into a silicon nitride film, the nitride layer 82 is formed into a silicon oxy-nitride film higher in nitrogen concentration than the nitride layer 22, the nitride layer 83 is formed into a silicon oxy-nitride film, and the nitride layer 84 is formed into a silicon nitride film. The nitride layers 81, 82, 83 and 84 are together regarded as one continuous nitride layer 8.

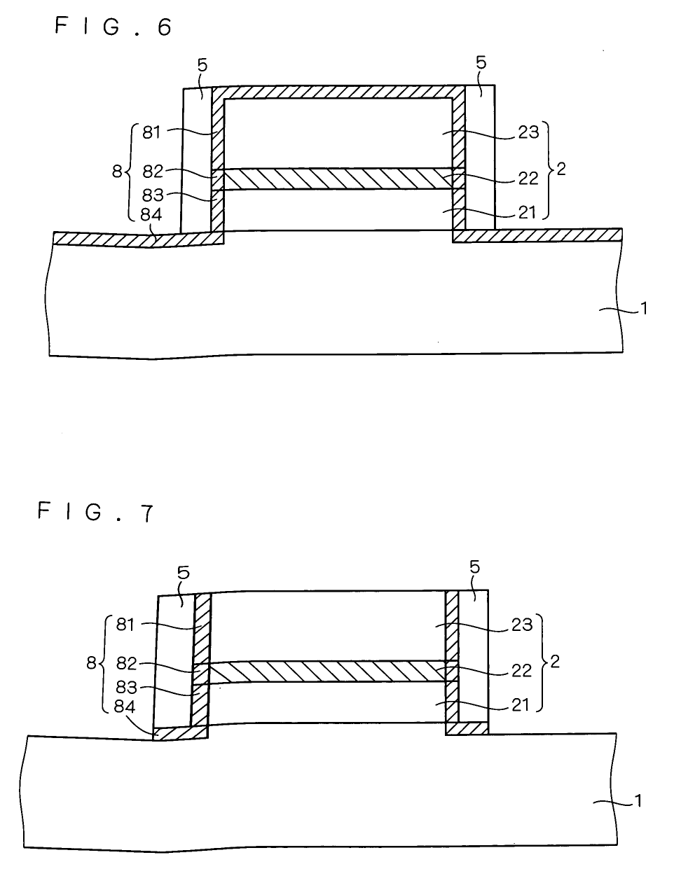

In a third step, an offset spacer 5 is provided to be in contact via the nitride layer 8 with the side surface of the gate structure 2 and some parts of the surface of the semiconductor substrate 1 in the vicinity of the side surface of the gate structure 2 (FIG. 6). The offset spacer 5 is formed for example by pattern etching of an organic film or an insulation film such as an oxide film deposited on the semiconductor substrate 1.

In a fourth step, exposed portions of the nitride layer 8 are removed for example by pattern etching, whereby the nitride layer 8 is defined by a portion of the nitride layer 81 on the side surface of the semiconductor film 23, by the nitride layers 82, 83, and by a portion of the nitride layer 84 under the offset spacer 5. Then the surface of the semiconductor film 23 of the gate structure 2 and the surface of the semiconductor substrate 1 opposite to the gate structure 2 with respect to the offset spacer 5 are exposed (FIG. 7).

When pattern etching is employed in each of the third and fourth steps, the pattern etching employed in the third step may be continued in the fourth step.

Defining a portion of the nitride layer 81 on the side surface of the semiconductor film 23 and the nitride layers 82, 83 as first portions of the nitride layer 8, and defining the nitride layer 84 after being subjected to pattern etching as a second portion of the nitride layer 8, the above-discussed second, third and fourth steps will be described as follows.

Namely, in the second step, the nitride layer 8 is formed which includes at least the first portions 81, 82 and 83 covering the side surface of the gate structure 2, and the second portion 84 extending from the first portions 81, 82 and 83 while covering a part of the exposed surface of the semiconductor substrate 1. In the third step, the offset spacer 5 is formed on the second portion 84 to cover the side surface of the gate structure 2 with the nitride layer 8 held therebetween. In the fourth step, the nitride layer 8 is removed while leaving the first portions 81, 82, 83 and the second portion 84 unremoved.

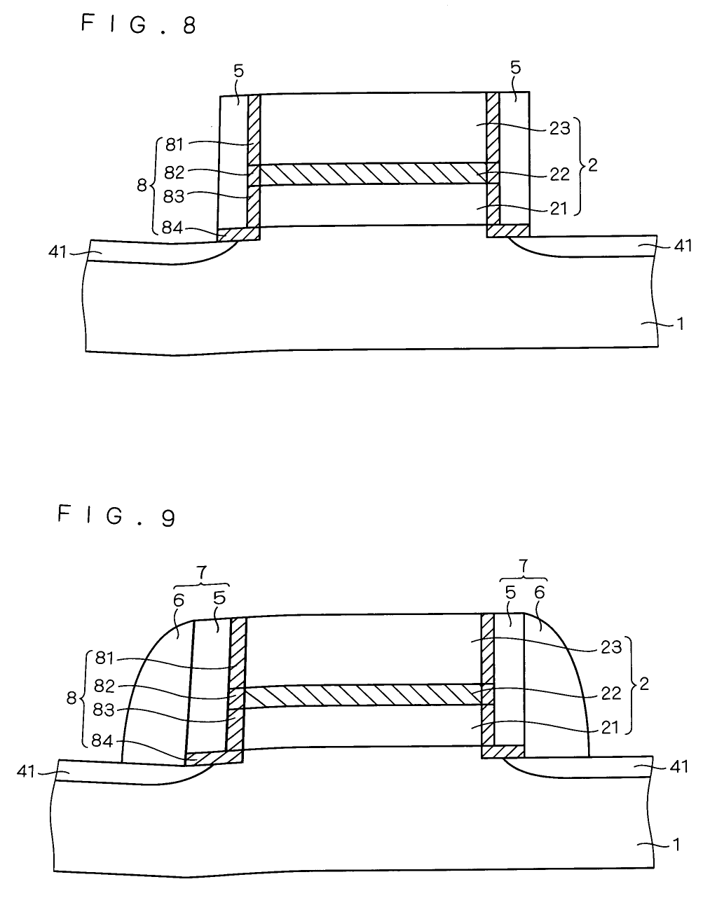

In a fifth step, impurities are implanted into the surface of the semiconductor substrate 1 using the gate structure 2 and the offset spacer 5 as a mask to thereby form source/drain regions 41 to be exposed from the surface of the semiconductor substrate 1 (FIG. 8). At this time, the impurities may also be implanted into the offset spacer 5. Further, the impurities implanted into the semiconductor substrate 1 may be present under the offset spacer 5.

Impurities may also be implanted into the semiconductor film 23 concurrently with the formation of the source/drain regions 41, in which case the source/drain regions 41 and the semiconductor film 23 are subjected to the implantation of impurities of the same type which may for example be boron. As this time, the impurities may also be implanted into the offset spacer 5.

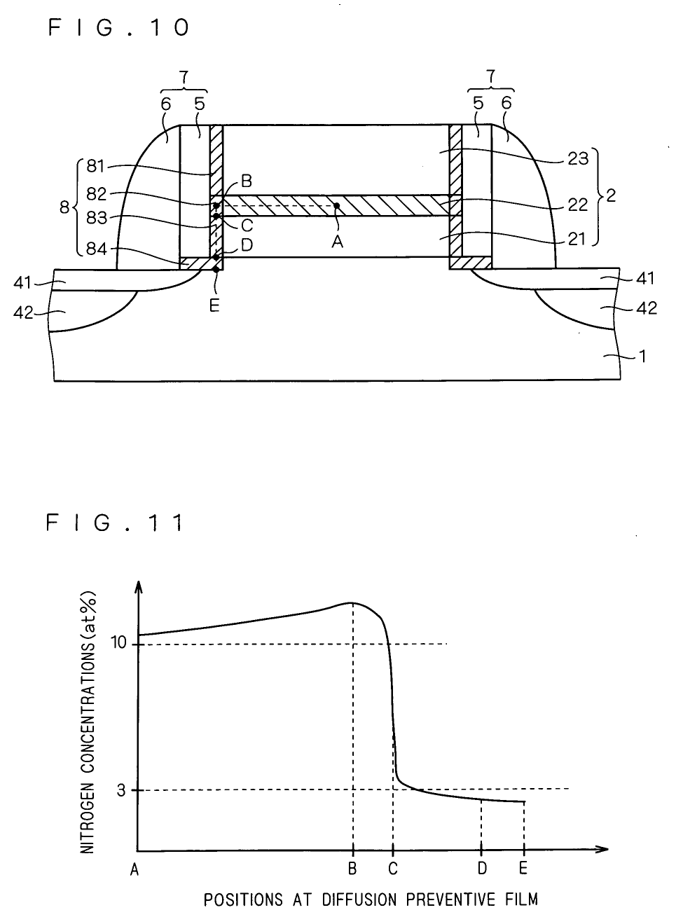

In a sixth step, a sidewall 6 is provided on the semiconductor substrate 1 (FIG. 9). The sidewall 6 is in contact with the source/drain regions 41 while covering the exposed side surface of the offset spacer 5 and the end surface of the nitride layer 84.

Thereafter using the gate structure 2, the offset spacer 5 and the sidewall 6 as a mask, impurities are implanted into the semiconductor substrate 1 to thereby form source/drain regions 42 under the source/drain regions 41 (FIG. 10).

A following step is thermal processing at a temperature for example of 1150° C. at which impurities are given a high diffusion coefficient. With regard to boron in a silicon crystal as an example, a diffusion coefficient of 10⁻¹³ cm²/s is given at 1150° C. to provide ease of diffusion.

The nitride layer 22 contains nitrogen, and hence impurities in the semiconductor film 23 which are especially boron can be prevented from diffusing into the insulation layer 21 and further into the semiconductor substrate 1. Thus the semiconductor device does not suffer from characteristic deterioration such as for example increase in leakage current or fluctuations in threshold voltage.

In some cases, the semiconductor film 23 contains hydrogen which is likely to diffuse into the insulation film 21. The diffusion of hydrogen into the insulation film 21 causes deterioration in TDDB (Time Dependence Dielectric Breakdown) characteristic of the semiconductor device.

In response, the nitride layer 22 is capable of preventing diffusion of hydrogen into the insulation film 21, thereby avoiding deterioration in TDDB (Time Dependence Dielectric Breakdown) characteristic of the semiconductor device.

The nitride layer 22 is located at the interface between the insulation film 21 and the semiconductor film 23, and is far from the semiconductor substrate 1. Thus the semiconductor device does not suffer from deterioration in tolerance to NBTI (Negative Bias Temperature Instability) which is likely to occur in the case of existence of nitrogen at the interface between the semiconductor substrate 1 and the insulation film 21.

The nitride layer 8 contains nitrogen, and hence impurities in the semiconductor film 23 which are especially boron are prevented from diffusing by way of the offset spacer 5 into the insulation film 21, and further into a portion of the semiconductor substrate 1 defined under the gate structure 2. Or impurities in the offset spacer 5 are prevented from diffusing directly into the insulation film 21, and further into a portion of the semiconductor substrate 1 defined under the gate structure 2. Thus the semiconductor device does not suffer from characteristic deterioration such as for example increase in leakage current or fluctuations in threshold voltage.

The offset spacer 5 contains hydrogen in some cases. The nitride layer 8 prevents hydrogen from diffusing into the insulation film 21, thereby avoiding deterioration in TDDB characteristic of the semiconductor device.

The nitride layers 8 and 22 may contain elements other than nitrogen, and are desirably operative to function as layers capable of effectively avoid diffusion of impurities contained therein according to the type of impurities. Such layers and the above-discussed nitride layers 8 and 22 are capable of preventing diffusion of impurities, and hence can be regarded as diffusion preventive films.

Defining the nitride layer 8 as a first diffusion preventive film, the nitride layer 22 as a second diffusion preventive film, and the offset spacer 5 and the sidewall 6 collectively as a sidewall 7 in the discussion given above, the semiconductor device shown in FIG. 10 is described as follows.

That is, the semiconductor device includes the semiconductor substrate 1, the gate structure 2, the source/drain regions 41, the first diffusion preventive film 8 and the sidewall 7. The gate structure 2 includes the insulation film 21, the second diffusion preventive film 22 and the semiconductor film 23. The insulation film 21 is arranged on the semiconductor substrate 1. The semiconductor film 23 containing impurities is arranged over the insulation film 21. The second diffusion preventive film 22 is provided at the interface between the insulation film 21 and the semiconductor film 23, and is operative to prevent diffusion of impurities contained in the semiconductor film 23. The source/drain regions 41 are formed in the semiconductor substrate 1 while being exposed from the surface of the semiconductor substrate 1. The first diffusion preventive film 8 includes the first portions 81, 82, 83 covering the side surface of the gate structure 2, and the second portion 84 extending from the first portions 81, 82, 83 and covering the exposed surface of the semiconductor substrate 1 while exposing at least a part of the source/drain regions 41. The sidewall 7 is in contact with the source/drain regions 41 while covering a surface of the first diffusion preventive film 8 opposite to that facing the gate structure 2.

Defining the offset spacer 5 and the sidewall 6 as a first portion and a second portion of the sidewall 7, respectively, the sidewall 7 will be described as follows. That is, the sidewall 7 includes the first portion 5 arranged on the second portion 84 of the diffusion preventive film 8, and the second portion 6 arranged on the exposed surface of the source/drain regions 41 while adjoining the first portion 5.

According to the above-discussed semiconductor device and the method of manufacturing the same, the source/drain regions 41 are covered only partially by the second portion 84 of the first diffusion preventive film 8 at the surface of the semiconductor substrate 1. This reduces the electrical resistance of the source/drain regions 41, thereby allowing a drive current to easily flow in the semiconductor device. Further, as a result of the provision of the first and second diffusion preventive films 8 and 22, impurities are prevented from diffusing from the semiconductor film 23 and the first portion 5 of the sidewall 7 arranged on the second portion 84 of the first diffusion preventive film 8 into the insulation film 21, and further into the semiconductor substrate 1 defined under the insulation film 21. Thus characteristic deterioration of the smeiconductor device is avoided.

The provision of the first portion 5 of the sidewall 7, namely, the provision of the offset spacer 5 suppresses extension of the source/drain regions 41 under the gate structure 2. That is, areas of the semiconductor film 23 and the source/drain regions 41 opposed to each other via the nitride layer 22 and the insulation film 21 are reduced. This reduces the electrostatic capacity at the opposed areas to thereby improve the operating speed of the semiconductor device.

When the second portion 84 of the first diffusion preventive film 8 contains nitrogen, the deterioration in tolerance to NBTI of the semiconductor device may occur while preventing diffusion of boron into the semiconductor substrate 1. When the second portion 84 does not contain nitrogen, for example, the deterioration in tolerance to NBTI is less likely to occur in the semiconductor device while causing diffusion of boron. In view of this, the second portion 84 of the first diffusion preventive film 8 desirably contains nitrogen, and desirably has a nitrogen concentration d1 falling within the range of 0 at. %<d1≦3 at. % (at. %: atomic percent).

This reduces the deterioration in tolerance to NBTI of the semiconductor device while preventing diffusion of boron into the semiconductor device.

When the second diffusion preventive film 22 contains nitrogen, the second diffusion preventive film 22 desirably has a nitrogen concentration d2 of d2≧10 at. % in order to effectively avoid diffusion of boron from the semiconductor film 23 into the insulation film 21.

FIG. 11 conceptually shows nitrogen concentrations taken at points A, B, C, D and E shown in FIG. 10. The point A is defined at a central portion of the nitride film 22, the point B is defined inside the nitride layer 82, the point C is defined at an interface between the nitride layers 82 and 83, the point D is defined at an interface between the nitride layers 83 and 84, and the point E is defined at an interface between the nitride layer 84 and the semiconductor substrate 1. In the range from the nitride layer 22 toward the nitride layer 82 (between the points A and B), a nitrogen concentration is lowest at the point A and highest at the point B. The nitrogen concentration is not less than 10 at. % at the point A. A nitrogen concentration decreases with increasing proximity to the point C from the point B, steeply decreasing in the vicinity of the point C to a level around 3 at. %. A nitrogen concentration is not more than 3 at. % in the nitride layer 84 (between the points D and E).

In the above-discussed method of manufacturing the semiconductor device, a plasma nitriding process is preferably employed in the formation of the nitride layers 22 and 8. A plasma nitriding process is performed at a temperature for example of 400° C. using plasma.

A diffusion distance of boron is considerably small at a temperature of about 400° C. Thus the use of a plasma nitriding process avoids diffusion of boron in the formation of the nitride layers 22 and 8.

The gate structure 2 is allowed to have reduced dimensions by the use of a plasma nitriding process in the formation of the nitride layer 8. When the gate structure 2 is formed by lithography, the dimensions of the gate structure 2 depend on the wavelength of light for use in exposure, imposing limitations on the shrinkage of the gate structure 2. In response, a combined use of lithography and a plasma nitriding process more effectively realizes the shrinkage of the gate structure 2.

While the invention has been shown and described in detail, the foregoing description is in all aspects illustrative and not restrictive. It is therefore understood that numerous modifications and variations can be devised without departing from the scope of the invention.

1. A semiconductor device, comprising:
a semiconductor substrate;
a gate structure;
source/drain regions;
a first diffusion preventive film; and
a sidewall,
said gate structure including:
an insulation film provided on said semiconductor substrate;
a semiconductor film provided on said insulation film and containing impurities; and
a second diffusion preventive film provided at an interface between said insulation film and said semiconductor film,
said source/drain regions being provided in said semiconductor substrate while being exposed from a surface of said semiconductor substrate,
said first diffusion preventive film including:
a first portion covering a side surface of said gate structure; and
a second portion extending from said first portion, said second portion covering an exposed surface of said semiconductor substrate while exposing at least a part of said source/drain regions,
said sidewall being in contact with said source/drain regions while covering a surface of said first diffusion preventive film opposite to a surface facing said gate structure.

2. The semiconductor device according to claim 1, wherein said sidewall includes:
a first portion provided on said second portion ( of said first diffusion preventive film; and
a second portion adjoining said first portion of said sidewall and provided on an exposed surface of said source/drain regions.

3. The semiconductor device according to claim 1, wherein
at least either said first diffusion preventive film or said second diffusion preventive film prevents diffusion of said impurities.

4. The semiconductor device according to claim 3, wherein
said sidewall includes:
a first portion provided on said second portion of said first diffusion preventive film; and
a second portion adjoining said first portion of said sidewall and provided on an exposed surface of said source/drain regions.

5. The semiconductor device according to claim 1, wherein
said first diffusion preventive film contains nitrogen.

6. The semiconductor device according to claim 5, wherein
said second diffusion preventive film contains nitrogen.

7. The semiconductor device according to claim 6, wherein
said second diffusion preventive film has a nitrogen concentration d2 of d2≧10 at. % (at. %: atomic percent).

8. The semiconductor device according to claim 5, wherein
said second portion of said first diffusion preventive film has a nitrogen concentration d1 of 0 at. %<d1≦3 at. % (at. %: atomic percent).

9. The semiconductor device according to claim 8, wherein
said second diffusion preventive film contains nitrogen.

10. The semiconductor device according to claim 9, wherein
said second diffusion preventive film has a nitrogen concentration d2 of d2≧10 at. % (at. %: atomic percent).

11. The semiconductor device according to claim 1, wherein
said second diffusion preventive film contains nitrogen.

12. The semiconductor device according to claim 11, wherein
said second diffusion preventive film has a nitrogen concentration d2 of d2≧10 at. % (at. %: atomic percent).

13. A method of manufacturing a semiconductor device, comprising the steps of:
(a) providing a gate structure on a semiconductor substrate;
(b) providing a first diffusion preventive film including at least a first covering a side surface of said gate structure and a second portion extending from said first portion while covering a part of an exposed surface of said semiconductor substrate;
(c) providing an offset spacer on said second portion to cover said side surface of said gate structure with said first diffusion preventive film held therebetween;
(d) removing said first diffusion preventive film while leaving said first portion and said second portion unremoved;
(e) implanting impurities into a surface of said semiconductor substrate using said offset spacer as a mask to form source/drain regions to be exposed from said surface of said semiconductor substrate; and
(f) providing a sidewall to be in contact with said source/drain regions while covering an exposed side surface of said offset spacer,
said step (a) including the steps of:
(a-1) providing an insulation film, a second diffusion preventive film and a semiconductor film from bottom to top in this order in a stacked structure on said semiconductor substrate; and
(a-2) removing said insulation film, said second diffusion preventive film and said semiconductor film while leaving a predetermined region (S) unremoved.

14. The method of manufacturing a semiconductor device according to claim 13, wherein
in said step (b), a plasma nitriding process is performed to form said first diffusion preventive film on exposed surfaces of said gate structure and said semiconductor substrate.

15. The method of manufacturing a semiconductor device according to claim 14, wherein
said second portion of said first diffusion preventive film has a nitrogen concentration d1 of 0 at. %<d1≦3 at. % (at. %: atomic percent).

16. The method of manufacturing a semiconductor device according to claim 13, wherein
said semiconductor film contains impurities, and
at least either said first diffusion preventive film or said second diffusion preventive film prevents diffusion of said impurities.

17. The method of manufacturing a semiconductor device according to claim 16, wherein
in said step (b), a plasma nitriding process is performed to form said first diffusion preventive film on exposed surfaces of said gate structure and said semiconductor substrate.

18. The method of manufacturing a semiconductor device according to claim 17, wherein
said second portion of said first diffusion preventive film has a nitrogen concentration d1 of 0 at. %<d1≦3 at. % (at. %: atomic percent).

19. The method of manufacturing a semiconductor device according to claim 13, wherein
in said step (a-1), a plasma nitriding process is performed to form said second diffusion preventive film on a surface of said insulation film opposite to a surface facing said semiconductor substrate.

20. The method of manufacturing a semiconductor device according to claim 19, wherein
said second diffusion preventive film has a nitrogen concentration d2 of d2≧10 at. % (at. %: atomic percent).
